(19) United States
(12) Patent Application Publication
(10) Pub. No.: US 2003/0085635 A1
(43) Pub. Date: May 8, 2003

(54) Multidimensional ultrasonic transducer arrays

(76) Inventor: Richard Davidsen, Everett, WA (US)

Correspondence Address: ATL ULTRASOUND, P.O. BOX 3003, 22100 BOTHELL EVERETT HIGHWAY, BOTHELL, WA, 98041-3003, US

(21) Appl. No.: 10/326,670

(22) Filed: Dec. 19, 2002

Related U.S. Application Data
(63) Continuation of application No. 09/714,030, filed on Nov. 15, 2000.

(51) Int. Cl. H01L 41/08

(52) U.S. Cl. 310/334

(57) ABSTRACT

A two dimensional ultrasonic transducer array stack is described which has a backing block of acoustically absorbent material formed of alternating plates of backing material and flex circuits adhesively bonded together. The thickness of the plates establishes the elevational dimension between the flex circuits and corresponds to the elevational pitch of the two dimensional array. The backing block may also be formed by photoetching conductive traces directly on the plates of backing material, which are then adhesively bonded together to form the backing block.

This invention relates to transducer probes for ultrasonic diagnostic imaging systems and, in particular, to such probes having elements extending in two or more dimensions.

An element in an array of acoustic elements used for ultrasonic imaging is excited by applying an electrical potential across the element by means of electrodes connected to opposite faces of the element. The applied potential causes the piezoelectric element to vibrate and thus transmit an ultrasound wave. During reception the element is vibrated by sound waves which are converted into an electrical signal conducted to the image processing system by the same electrodes used to excite the element. When the piezoelectric element is one of a single row of elements in a transducer array such as one used for two dimensional ultrasonic imaging, there are a number of options for making the connections of the electrodes to opposite faces of the elements. In particular, it is common to make connections from the sides of the array, apart from the acoustic backing block which damps undesired acoustic energy behind the array.

However, when the transducer array comprises a two dimensional array, it becomes difficult to make all of the connections to the elements from the side of the array. This is because, in the case of an array of three or more rows of elements, one or more rows are in the interior of the array with access blocked by the rows at the outsides of the array. In such case it generally becomes necessary to make connections through the acoustic backing of the transducer stack.

One prior art approach to making connections to a two dimensional array is shown in U.S. Pat. No. 4,825,115. In this patent flexible printed circuit (flex circuit) is attached to the back of a piezoelectric plate, then bent upward so that it extends perpendicular to the plate from its attachment points. The acoustic backing is then cast around the flex circuit, the assembly is turned over and the piezoelectric plate is diced into individual elements. U.S. Pat. No. 5,757,727 shows a similar approach, but rather than attach the flex circuit to the complete array area and cast the backing to the unitary assembly, individual subassemblies of backing and flex circuit are preformed and then assembled together to build up the assembly row by row. This approach requires tightly controlled consistency from row to row to assure uniform performance and conductor spacing. In addition, both of these techniques require that the conductors be bent at a 90 degree angle at their points of attachment to the transducer elements, which stresses the conductors and can lead to impedance variations and connection failures.

U.S. Pat. Nos. 6,043,590 and 6,044,533 show approaches which avoid the need to bend the conductors. Instead, the conductors abut the backs of the elements perpendicularly and are not bent. In addition the conductors and backing material are preformed as a unitary assembly and can be inspected for the necessary interelement alignment before being attached to the piezoelectric material. In the latter case, dielectric substrates with windows of bare conductors are stacked, and the spaces between the conductors are filled with an attenuating material. When the material cures the immobilized stack is cut through the material to produce a backing block with the conductors terminating at the cut surface. However this process is prone to difficulties in maintaining the alignment of the bare conductors, and of completely filling the spaces around them without leaving pockets of air. It would therefore be desirable to be able to produce such a conductive backing assembly in a way that is simple, precise, and highly repeatable.

In accordance with the principles of the present invention, an ultrasonic transducer probe includes a two dimensional array of acoustic elements, to which conductors are attached by way of a conductive backing block assembly. The assembly comprises a plurality of alternating flex circuits and plates of backing material which are adhesively attached to form a unitary assembly. Alternatively, the conductive traces can be formed directly on the plates, which are then bonded together. The assembly does not bend the conductors and can be easily and accurately fabricated using conventional transducer assembly processes.

In the drawings:

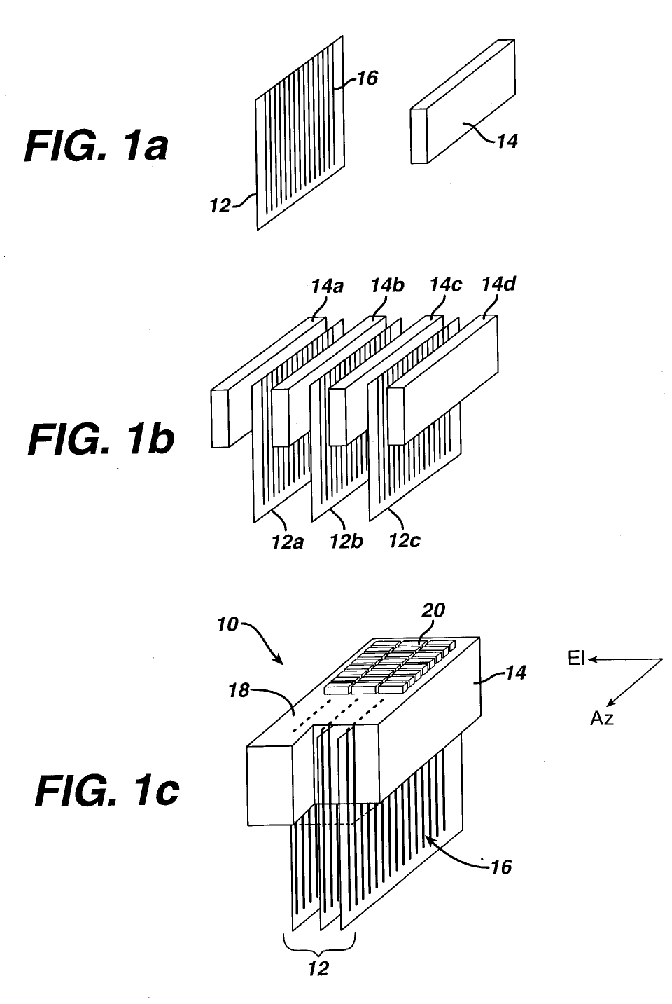

FIGS. 1a-1c illustrate a first embodiment of an ultrasonic transducer stack with a conductive backing block constructed in accordance with the principles of the present invention;

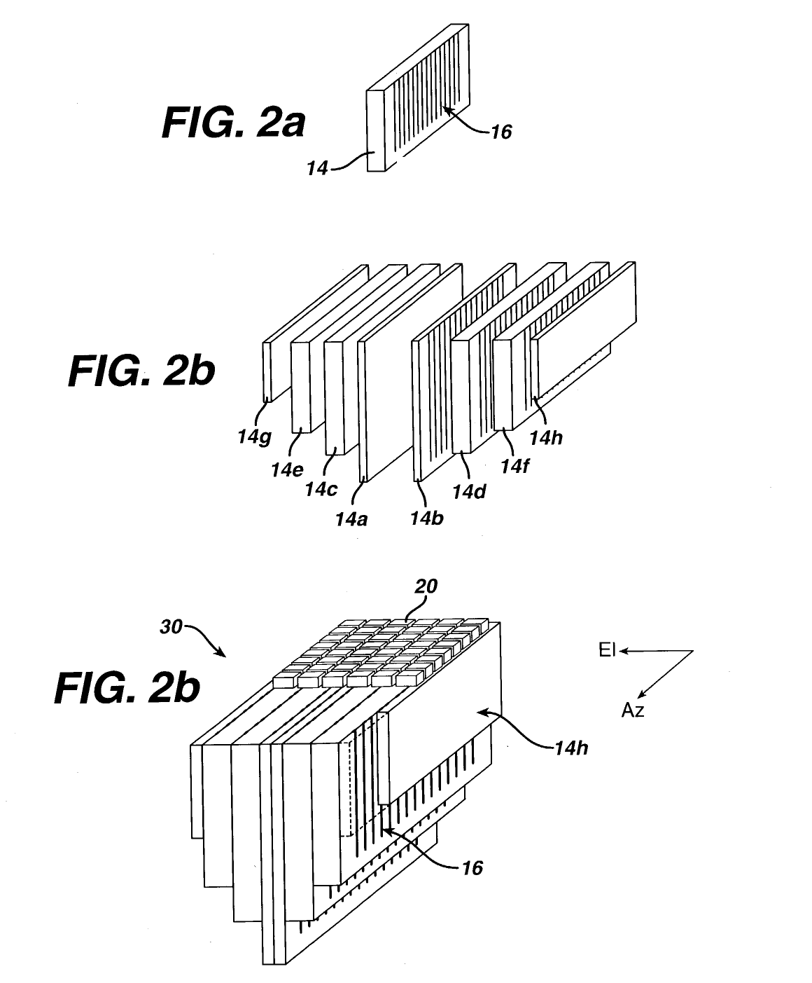

FIGS. 2a-2c illustrate a second embodiment of an ultrasonic transducer stack with a conductive backing block constructed in accordance with the principles of the present invention;

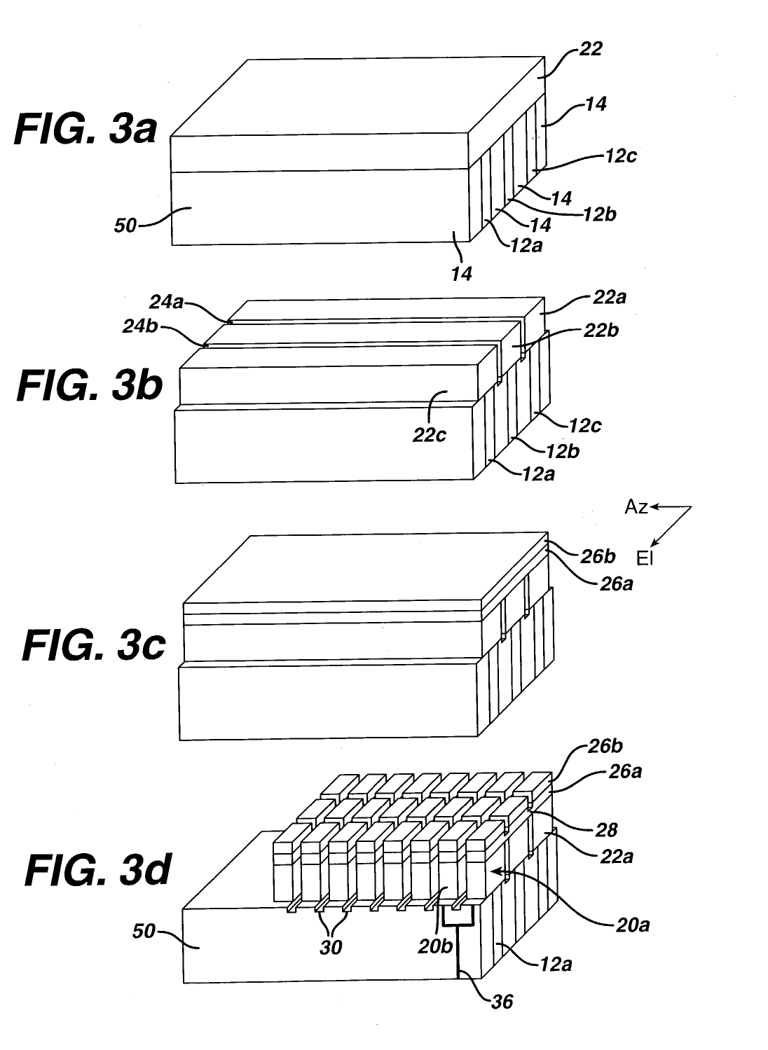

FIGS. 3a-3d illustrate an ultrasonic transducer stack with subdiced transducer elements constructed in accordance with the principles of the present invention;

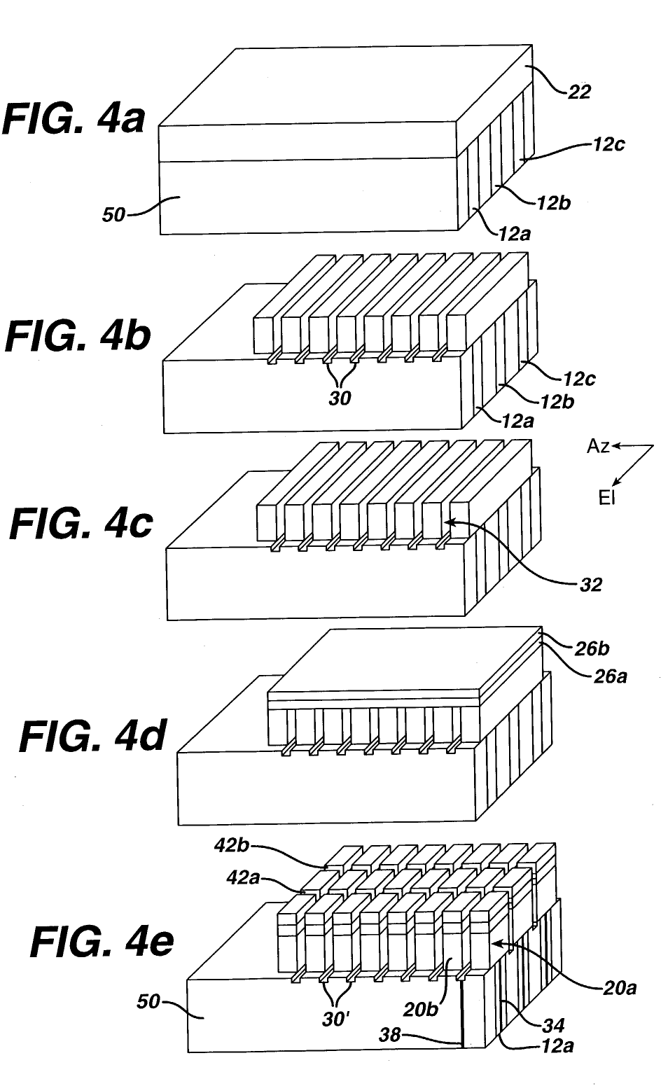

FIGS. 4a-4e illustrate an ultrasonic transducer stack with transducer elements operating in the k₃₁ mode and constructed in accordance with the principles of the present invention;

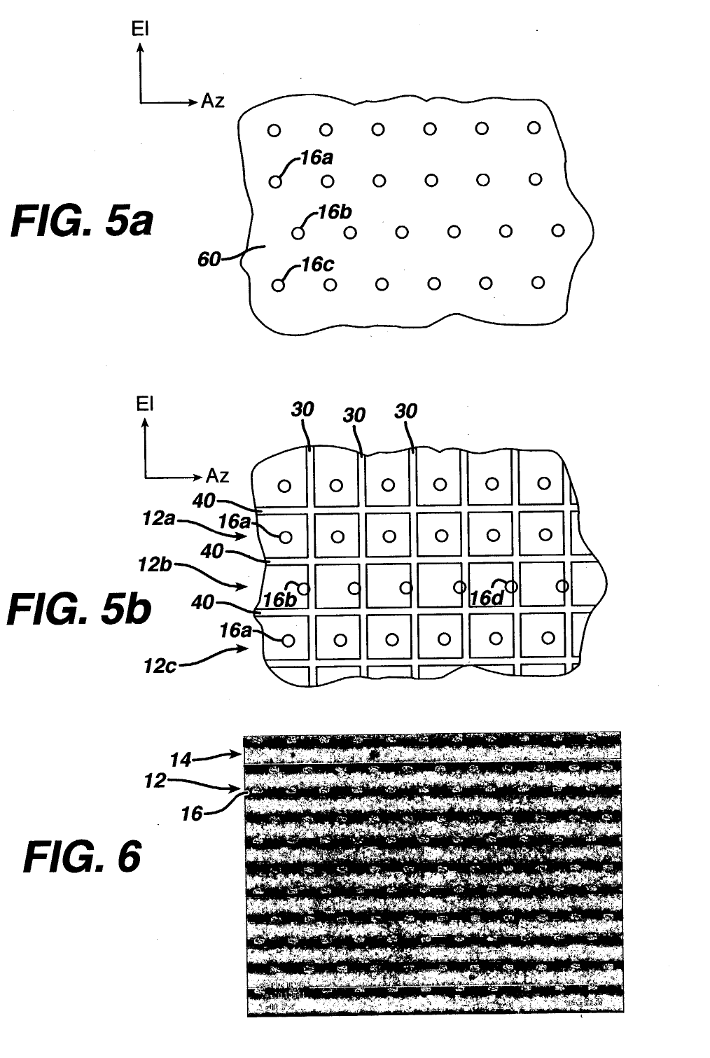

FIGS. 5a and 5b illustrate the alignment of conductors in a backing block of the present invention with respect to the transducer element footprints; and

FIG. 6 is a microphotograph of a conductive backing block of the present invention for a two dimensional hexagonal array.

Referring first to FIGS. 1a-1c, the steps for assembling a conductive backing block for a two dimensional (2D) ultrasonic array transducer stack are shown in perspective views. The backing block assembly has two primary components, a flex circuit 12 and a backing block plate 14. The flex circuit comprises an insulated substrate such as a sheet of Kapton on which are formed a plurality of conductive traces 16, generally by a photoetching process. Typically the Kapton sheet may have a thickness of 1-3 mils. (25 μn-75 μm). In FIG. 1a the traces 16 are shown ending at the top of the Kapton substrate, however, in a constructed embodiment it is often desirable to have the traces extend slightly beyond the upper edge of the substrate as shown in the microphotograph discussed below. The extension of the traces offsets the substrate from the point of contact of the traces and the transducer elements which eliminates problems with the thermal expansion of the Kapton at that juncture. Acoustic impedance immediately behind the transducer element is better controlled and Kapton particles are reduced or completely eliminated from the grinding and dicing processes. The lower terminations of the traces 16 usually end in conductive pads (not shown) so that the traces may be connected to other printed circuits or components.

The backing block plate 14 is formed from a sheet of backing material that has a predetermined thickness. Backing blocks are usually cast from epoxies mixed with ultrasonic absorbers and scatterers such as microballoons and small particles. The mixtures of these materials are controlled as is known to give the backing block a predetermined acoustic impedance and attenuation. The backing block plate 14 has a predetermined thickness which is obtained by a controlled grinding process.

In accordance with the principles of the present invention, a conductive backing block assembly is constructed from alternating layers of flex circuits 12a-12c and plates 14a-14d of backing material, as shown in the exploded view of FIG. 1b, which are laminated together with an adhesive such as an epoxy. Preferably the plates 14a-14d are cut from the same sheet of backing material so that the plates will all exhibit the same composition and hence have the same acoustic properties, and will be ground to the same controlled thickness. In a constructed embodiment the assembly is cured under pressure in a heated press. The compression squeezes out excess epoxy so that the alternating flex circuits will be evenly spaced in the elevation dimension, and will also expel air bubbles from between the layers. When the assembly is cured the top surface to which connections are made to the transducer elements 20 is ground to a smooth finish and preferably gold plated for attachment to the underside of the transducer elements, which are also preferably gold plated. The preferred method for connecting the conductive backing block assembly to the transducer elements is by adhesive attachment using a low viscosity adhesive such as an epoxy. The low viscosity results in direct ohmic contact between the gold plating on the conductive backing assembly and the transducer elements while at the same time forming a secure adhesive bond between the two surfaces. The assembled transducer stack 10 is shown in FIG. 1c, with the arrows to the right of the drawing indicating the azimuth (Az) and elevation (E1) dimensions. Generally the row of traces of each flex circuit 12 will constitute the azimuth dimension of the array, and the flex circuit to flex circuit spacing will constitute the elevation dimension, although this can be reversed. The customary use is generally the case for 1.5D arrays which are steered and focused in a single azimuth plane but only focused in the elevation dimension. A 2D array for three dimensional imaging, in which steering and focusing is performed in the volume in front of the array, will generally be described by polar coordinates as it will often have no definable azimuth and elevation dimensions. For instance, the overall array may be circular or octagonal in its perimeter. However this nomenclature will be used in this application for clarity and to maintain a consistent point of reference for the drawings.

It will be appreciated that the assembly of the present invention could alternatively be constructed using rigid (e.g., FR4) printed circuit boards in place of the flexible printed circuits. Flex circuits are preferred for their thin profile and for the ease with which they can be fabricated to form traces extending beyond the substrate.

FIGS. 2a-2c show a second embodiment of the present invention. In this embodiment there are no flex circuits. Instead, the conductive traces 16 are formed directly on the backing block plates 14, which may be done by a photoetching process. Thus, the elevational spacing (pitch) of the transducer elements will not include the thickness of the flex circuit substrate in this embodiment. As before, the traces 16 may end in interconnect pads at the bottom but, unlike the flex circuits, will not need to extend above the top edges of the plates 14. The conductive backing block assembly is formed as shown in the exploded view of FIG. 2b. In this particular embodiment the backing block plates 14a-14h are of progressively differing lengths so that all of the terminating ends of the traces (which do not extend beyond the bottoms of the plates in this embodiment) may be accessed for connections. Alternatively the backing block plates may be of the same length so that the traces terminate at the lower surface of the backing block assembly just as they do at the upper surface. In this case the traces may terminate in a pad grid array on the lower surface for contact by a connector which mates with the lower surface of the assembly and its traces. The two central plates 14a and 14b in the illustrated example are of half thicknesses compared to their surrounding plates so that the oppositely facing traces on the plates will be centered with respect to the two central rows of an even number of rows of transducer elements. If there were an odd number of element rows a single plate of full thickness would be used in the center of the assembly. The end cap plates 14g and 14h have no elements formed on them as they are used only to enclose the rest of the assembly while providing support for the outermost rows of elements. The final processing of the conductive backing assembly and attachment of the transducer elements is completed as described above. The finished transducer stack 30 is shown in a partial breakaway view and with a partial element assembly in FIG. 2c to reveal the trace alignment within and across the top surface of the conductive backing assembly.

FIGS. 3a-3c illustrate further details of the construction of a transducer stack of the present invention with a conductive backing block assembly. In these drawings the conductive backing block assembly 50 comprises alternating layers of flex circuits 12 and backing plates 14, although the assembly could also be formed of backing plates with conductive traces formed thereon as described above. In FIG. 3a the conductive backing block assembly is gold plated on top and adhesively attached to a piezoelectric plate 22 which is gold plated on the top and the bottom. In the assembly 50 below the piezoelectric plate are three flex circuits 12a, 12b, and 12c which in this example extend in the azimuth dimension. In FIG. 3b the piezoelectric plate 22 is diced in the azimuth dimension by two cuts 24a and 24b, thereby forming three rows of piezoelectric 22a, 22b, and 22c, each of which is located above a respective flex circuit 12a, 12b, and 12c. The cuts extend through the interface of the gold plating between the assembly 50 and the piezoelectric 22 to thereby electrically separate the electrical connection of the flex circuit under each row of piezoelectric.

Two matching layers 26a and 26b are laid over the piezoelectric as shown in FIG. 3c. The matching layers match the acoustic impedance of the transducer to the body into which it transmits and from which it receives acoustic signals. Prior to laying the matching layers a conductive sheet (not shown) may be laid over the upper surface of the piezoelectric which, as mentioned above, has been gold plated. This conductive sheet will provide electrical connections to the upper face of each piezoelectric element. Preferably surface of matching layer 26a which contacts the piezoelectric is metallized to provide the connections to the upper faces of the transducer elements. In FIG. 3d the piezoelectric rows are diced completely through the interface of the gold plating between the assembly 50 and the piezoelectric 22 in the elevation dimension as indicated at 30 to form individual transducer elements and to electrically separate the gold plated contacts under each individual transducer element. Orthogonal dicing cuts are also made in the azimuth direction in line with the previous cuts 24a and 24b to mechanically separate the matching layers of each row of elements. As shown at 28, these cuts do not extend completely through the lower matching layer 26a, thereby leaving continuous strips of the conductive sheet across each line of elements in the elevation dimension. Thus, electrical connection to the upper electrodes of all of the elements, including those in the interior of the array, can be made from either elevational side of the array.

In this particular example subdiced elements are formed, whereby each adjacent pair of subdiced elements in azimuth are operated as a unitary element for better high frequency performance. One such pair comprises subelements 20a and 20b, which are connected to a single trace of the underlying flex circuit 12a as indicated by the projection of Y-shaped conductor 36 of flex circuit 12a onto the side of the assembly 50. The Y shape at the top of the conductor which splits off a conductor to each subelement enables the cuts 30 to be made into the assembly 50 without contamination of the dicing saw by bits of the flex circuit conductors. In addition to being subdiced in the azimuth direction, subdicing may also be done in the elevation dimension of the elements to improve acoustic performance.

FIGS. 4a-4e illustrate the construction of a transducer stack of the present invention which is to be operated in the k₃₁ mode as described, for instance, in U.S. patent [application Ser. No. 09/457,196, filed Dec. 3, 1999 ]. Rather than conventional excitation longitudinally between the top (patient-facing side) and bottom of the element, in the k₃₁ mode a transducer element is poled and excited laterally. This enables the electrodes of the element to be located on the sides of an element rather than the top and bottom. In the example of FIG. 4a the piezoelectric plate 22 is adhesively attached to the conductive backing block assembly 50 which contains embedded flex circuits 12a, 12b, and 12c, but could also comprise backing plates with etched conductors as described above. Unlike the example of FIG. 3, in this embodiment there are no gold plated electrodes between the piezoelectric plate and the assembly 50; the piezoelectric is simply attached to the finished surface of the assembly 50. In FIG. 4b the piezoelectric plate 22 is diced in the elevation dimension to form columns of piezoelectric material across the backing block and its rows of flex circuit 12a, 12b, and 12c. These dicing cuts 30 are made in line with conductive traces on the underlying flex circuit so that the ends of the traces are located in the bottoms of the cuts 30. In FIG. 4c the lateral, opposing walls 32 within the cuts 30 are plated with electrode material, which may be applied by wet plating, evaporation, or a sputtering process. This electrode material lines both lateral piezoelectric walls 32 of the dicing cuts 30, as well as the bottom of the cut where the conductive traces end. Thus, this electroding electrically connects the conductive traces in the bottom of the cuts to the lateral sides of the piezoelectric on either side of the respective cuts.

In FIG. 4d the matching layers 26a and 26b are applied. In this embodiment there is no need for any plated electrodes or sheets on top of the piezoelectric, since all electrical connections are made from the bottom through the flex circuit conductors. The 2D array is finished in FIG. 4e by dicing the matching layers in the elevation dimension in line with the previous cuts 30, and by dicing the piezoelectric columns in the azimuth dimension as indicated at 42a and 42b to form separate rows of individual transducer elements extending in the azimuth dimension. The dicing cuts 42a and 42b are made into the upper surface of the conductive backing block 50 and through the conductive material in the intersected bottoms of the cuts 30 so as to electrically separate the respective rows of elements. Subdiced pairs of subelements are now operated in the k₃₁ mode by connections from the flex circuit conductors, with the conductors in the sequential cuts in a row alternately providing signal (hot) and return (ground) paths through an underlying flex circuit trace. For instance, the transducer element formed by subelements 20a and 20b have the lateral facing electrode surfaces connected to a conductor 38 on the flex circuit 12a underlying that row of elements, as shown in projection in FIG. 4e. The opposite lateral sides of the subelements are connected to a conductor 34 of the flex circuit 12a and to a conductor terminating at the bottom of dicing cut 30′ (not shown), which provide common or ground potential at these other electroded sides of the subelements. Thus all electrical connections to the transducer elements can be made through the conductive traces of the conductive backing block 50.

In the case of the transducer elements connected at the bottom to the plated surface of the conductive backing block, the combination of the conductive traces and the plating on the surface enable a high yield of transducer stacks from the manufacturing process, as perfect alignment of the conductors is not required. For instance, FIG. 5a is a plan view of the gold plated surface 60 of a connective backing block which is intersected by the ends of conductive traces 16a, 16b, and 16c passing through the backing block. Four horizontal rows of conductive traces are shown which extend from four horizontally arranged flex circuits or backing plate surfaces. It is seen that the top, second and bottom row are in vertical alignment in this example, but that the third row which contains conductive trace 16b is not in vertical alignment with the others. When the piezoelectric plate is attached to the plated surface 60 and diced into separate transducer elements centered with respect to the aligned conductive traces, the plated surface is separated into plated areas matching the bottom footprint of the elements as shown in FIG. 5b. The plated areas are separated by the dicing cuts 30, 40. The conductive traces in rows 12a and 12c are seen to be nicely aligned with the center of the plated areas of the respective element footprints, as was intended. The misaligned conductive traces of row 16b, while not aligned at the center of the plated areas, will still function as desired, as each still intersects the intended plated area. Even a dramatically offcenter trace such as 16d will still provide satisfactory electrical connection to its plated area. In a particular embodiment the plated area may have a thickness of about 0.5 μm and perimeter dimensions on the order of 200 μm by 200 μm, and the width of a conductive trace 16 may be on the order of 50 μm, giving the trace a placement tolerance of 4:1 in each orthogonal direction. The elevational accuracy is maintained by controlling the thickness of the backing block plates as they are ground to the desired thickness. A subdiced element may have two subelements with dimensions of 125 μm by 250 μm, which still allows a relatively broad tolerance. As transducer elements and hence the plated area footprints become even smaller and approach 50 μm by 50 μm, conductive traces are anticipated to become correspondingly smaller.

FIG. 6 is a microphotograph of the top surface of a conductive backing block of the present invention before the surface has been plated. This microphotograph clearly shows the alternating horizontal rows of flex circuit 12 and backing block plates 14. The ends of the conductive traces 16 extending from the flex circuits is clearly visible in the microphotograph. The black areas between these conductive traces 16 in each row are voids which have been filled with the epoxy adhesive which binds the assembly together. In this illustration the ends of the conductive traces extend above their Kapton substrate to their point of termination at the surface of the conductive backing assembly.

This microphotograph also shows that the rows of flex circuit are alternately aligned in a staggered arrangement from row to row. That is because this particular conductive backing assembly has been designed for a hexagonal 2D array transducer, in which transducer elements repeat a triangular relationship to each other to form hexagonal groupings. Such a 2D hexagonal array is described in U.S. patent [application Ser. No. 09/488,583, filed Jan. 21, 2000 ], for instance. The present invention is thus applicable to rectilinear 2d arrays as well as other shapes and configurations such as hexagonal arrays.

While the illustrated embodiments are shown using piezoelectric transducers, the present invention is equally applicable to other transducer technologies such as capacitive and piezoelectric micromachined transducers (Cmuts and Pmuts), which may also be electrically connected through a conductive backing block assembly. Cmut transducers are shown in U.S. Pat. No. 5,619,476, for instance.

What is claimed is:

1. A two dimensional ultrasonic transducer array probe comprising:
a two dimensional array of ultrasonic transducer elements having a bottom surface from which undesired ultrasonic energy is emitted; and
a conductive backing block assembly affixed in opposition to the bottom surface of the two dimensional array which comprises separate alternating plates of acoustic backing material and printed circuit substrates with conductive traces, the separate plates and printed circuit substrates being bonded together with adhesive located between the adjoining surfaces of the plates and the printed circuit substrates.

2. The two dimensional ultrasonic transducer array probe of claim 1, wherein the printed circuit substrates comprise flex circuits.

3. The two dimensional ultrasonic transducer array probe of claim 2, wherein the plates of acoustic backing material exhibit a thickness chosen to establish a predetermined elevational spacing between the flex circuits.

4. The two dimensional ultrasonic transducer array probe of claim 3, wherein the plates of acoustic backing material contain acoustic absorbent material and acoustic scatterers.

5. The two dimensional ultrasonic transducer array probe of claim 2, wherein the flex circuits extend beyond the ends of the plates at one end and the conductive traces of the flex circuits terminate at the other end at a surface of the conductive backing block assembly which opposes the two dimensional array.

6. The two dimensional ultrasonic transducer array probe of claim 5, wherein the surface of the conductive backing block assembly at which the conductive traces terminate is conductively plated, wherein the conductive plating is in electrical contact with the conductive traces.

7. The two dimensional ultrasonic transducer array probe of claim 6, wherein the conductively plated surface is divided into electrically separate areas corresponding to the footprint of elements of the array transducer when the transducer array is diced.

8. The two dimensional ultrasonic transducer array probe of claim 1, wherein the adhesive is an epoxy adhesive.

9. A two dimensional ultrasonic transducer array probe comprising:
a two dimensional array of ultrasonic transducer elements having a bottom surface from which undesired ultrasonic energy is emitted; and
a conductive backing block assembly affixed in opposition to the bottom surface of the two dimensional array which comprises a series of plates of acoustic backing material with conductive traces formed thereon which are adhesively bonded together.

10. The two dimensional ultrasonic transducer array probe of claim 9, wherein the plates of acoustic backing material exhibit a thickness chosen to establish a predetermined elevational spacing between the conductive traces.

11. The two dimensional ultrasonic transducer array probe of claim 10, wherein the plates of acoustic backing material contain acoustic absorbent material and acoustic scatterers.

12. The two dimensional ultrasonic transducer array probe of claim 9, wherein the plates exhibit different lengths so as to provide access to the conductive traces, and the conductive traces terminate at a surface of the conductive backing block assembly which opposes the two dimensional array.

13. The two dimensional ultrasonic transducer array probe of claim 9, wherein the conductive traces terminate at a pad grid array on a surface of the conductive backing block where connections to the assembly are made.

14. The two dimensional ultrasonic transducer array probe of claim 9, wherein the surface of the conductive backing block assembly at which the conductive traces terminate is conductively plated, wherein the conductive plating is in electrical contact with the conductive traces.

15. The two dimensional ultrasonic transducer array probe of claim 14, wherein the conductively plated surface is divided into electrically separate areas corresponding to the footprint of elements of the array transducer when the transducer array is diced.

16. The two dimensional ultrasonic transducer array probe of claim 9, wherein the adhesive is an epoxy adhesive.

17. A conductive backing block assembly for a two dimensional ultrasonic transducer array comprising:
plates of acoustic backing material; and
printed circuit substrates located between the plates of acoustic backing material and having conductive traces,
wherein the plates and printed circuit substrates are bonded together with adhesive located between the adjoining surfaces of the plates and printed circuit substrates.

18. The conductive backing block assembly of claim 17, wherein the printed circuit substrates comprise flex circuits.

19. The conductive backing block assembly of claim 18, wherein the conductive traces of the flex circuits terminate at a surface of the assembly at which electrical connections are to be made to a two dimensional transducer array.

20. A conductive backing block assembly for a two dimensional ultrasonic transducer array comprising:
plates of acoustic backing material having conductive traces formed thereon, wherein the plates are adhesively bonded together.

21. The conductive backing block assembly of claim 20, wherein the conductive traces terminate at a surface of the assembly at which electrical connections are to be made to a two dimensional transducer array.

22. The conductive backing block assembly of claim 21, wherein the plates are of different lengths so as to provide access to the conductive traces at a side of the assembly.

23. The conductive backing block assembly of claim 21, wherein the conductive traces terminate at a pad grid array on a surface of the conductive backing block assembly where connections to the assembly can be made.

24. A two dimensional ultrasonic transducer array probe comprising:
a two dimensional array of micromachined ultrasonic transducer elements having a bottom surface from which undesired ultrasonic energy is emitted; and
a conductive backing block assembly affixed in opposition to the bottom surface of the two dimensional array which comprises separate alternating plates of acoustic backing material and printed circuit substrates with conductive traces, the separate plates and printed circuit substrates being bonded together with adhesive located between the adjoining surfaces of the plates and the printed circuit substrates.

25. The two dimensional ultrasonic transducer array probe of claim 24, wherein the printed circuit substrates comprise flex circuits.

26. The two dimensional ultrasonic transducer array probe of claim 25, wherein the micromachined ultrasonic transducer elements comprise capacitive micromachined transducer elements.

27. The two dimensional ultrasonic transducer array probe of claim 25, wherein the micromachined ultrasonic transducer elements comprise piezoelectric micromachined transducer elements.

28. A two dimensional ultrasonic transducer array probe comprising:
a two dimensional array of ultrasonic transducer elements having top faces, bottom faces, and electroded lateral faces which operate in the k₃₁ mode; and
a conductive backing block assembly affixed in opposition to the bottom faces of the two dimensional array elements which comprises alternating layers of acoustic backing material and printed circuit substrates with conductive traces bonded together.

29. The two dimensional ultrasonic transducer array probe of claim 28, wherein the printed circuit substrates comprise flex circuits.

30. The two dimensional ultrasonic transducer array probe of claim 29, wherein the conductive traces of the flex circuits are electrically coupled to the electroded lateral faces of the transducer elements.

31. A two dimensional ultrasonic transducer array probe comprising:
a two dimensional array of ultrasonic transducer elements having top faces, bottom faces, and electroded lateral faces which operate in the k₃₁ mode; and
a conductive backing block assembly affixed in opposition to the bottom faces of the two dimensional array elements which comprises a series of plates of acoustic backing material with conductive traces formed thereon which are bonded together.

32. The two dimensional ultrasonic transducer array probe of claim 31, wherein the conductive traces are electrically coupled to the electroded lateral faces of the transducer elements.
